(19) United States
(12) Patent Application Publication
(10) Pub. No.: US 2015/0200279 A1
(43) Pub. Date: Jul. 16, 2015

(54) METHOD OF MANUFACTURING MEMORY CELL

(71) Applicant: UNITED MICROELECTRONICS CORP., Hsin-Chu City (TW)

(72) Inventor: Shen-De Wang, Hsinchu County (TW)

(73) Assignee: UNITED MICROELECTRONICS CORP., Hsin-Chu City (TW)

(21) Appl. No.: 14/153,069

(22) Filed: Jan. 12, 2014

(51) Int. Cl. H01L 29/66; H01L 29/423; H01L 21/3213; H01L 29/51; H01L 21/28; H01L 21/311

(52) U.S. Cl. CPC H01L 29/66833; H01L 21/28282; H01L 21/31111; H01L 21/32133; H01L 21/31144; H01L 21/32139; H01L 29/511; H01L 29/518; H01L 29/42364

(57) ABSTRACT

A method of manufacturing a memory cell is provided. First, a substrate is provided. A patterned dielectric layer and a patterned first conductive layer are formed on the substrate. Then, a charge trapping structure and a main gate are formed on a sidewall of the patterned dielectric layer and the patterned first conductive layer. A portion of the patterned first conductive layer and a portion of the patterned dielectric layer are removed until exposing the substrate. Next, at least a source/drain region is formed in the substrate.

### BACKGROUND OF THE INVENTION

1. Field of the Invention

The present invention relates to a method of manufacturing a memory cell, and more particularly, to a method of manufacturing a memory cell having a selection gate with a vertical sidewall.

2. Description of the Prior Art

Semiconductor memory devices used for storing data can be divided into volatile devices and non-volatile devices. Volatile memory devices lose data stored therein when a supply voltage is interrupted, while non-volatile memory devices retain the data stored therein even if the supply voltage is interrupted. Accordingly, non-volatile memory devices are widely used when the supply voltage is not always applied or often interrupted, or when a device requires only a low voltage, such as a mobile telephone, a memory card for storing music and/or image data, and other application devices.

Cell transistors of the non-volatile memory device have a stacked gate structure. The stacked gate structure includes a gate insulating layer which is sequentially stacked on a channel region of the cell transistor, a floating gate electrode, an insulating layer between gates, and a control gate electrode. The non-volatile memory device often can be formed by a silicon layer in which a channel region is formed, an oxide layer which forms a tunneling layer, a nitride layer which is used as a charge trapping layer, an oxide layer which is used as a blocking layer, and a silicon layer which is used as a control gate electrode. This structure is referred to as a silicon-oxide-nitride-oxide-silicon (or SONOS) cell structure.

A conventional SONOS memory cell can perform forward read and reverse read to store electrons in the right side or left side of the charge trapping layer. With the shrinkage of semiconductor devices, however, the size of the charge trapping layer is reduced and the electrons stored therein are becoming fewer as well. This results in increased errors of the memory devices when programming or reading devices and thus affects the reliability of semiconductor products.

### SUMMARY OF THE INVENTION

The present invention therefore provides a method of manufacturing a memory cell, which has a better performance.

According to one embodiment of the present invention, a method of manufacturing a memory cell is provided. First, a substrate is provided. A patterned dielectric layer and a patterned first conductive layer are formed on the substrate. Then, a charge trapping structure and a main gate are formed on a sidewall of the patterned dielectric layer and the patterned first conductive layer. A portion of the patterned first conductive layer and a portion of the patterned dielectric layer are removed until exposing the substrate. Next, at least a source/drain region is formed in the substrate.

By using the method provided in the present invention, the selection gate can be defined more precisely because the photo window is released and the etching process is relatively easy. Both time and cost can be streamlined and products with good performance can be obtained.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 illustrate schematic diagrams of the method of fabricating a memory cell in accordance with one embodiment of the present invention.

### DETAILED DESCRIPTION

To provide a better understanding of the presented invention, preferred embodiments will be described in detail. The preferred embodiments of the present invention are illustrated in the accompanying drawings with numbered elements.

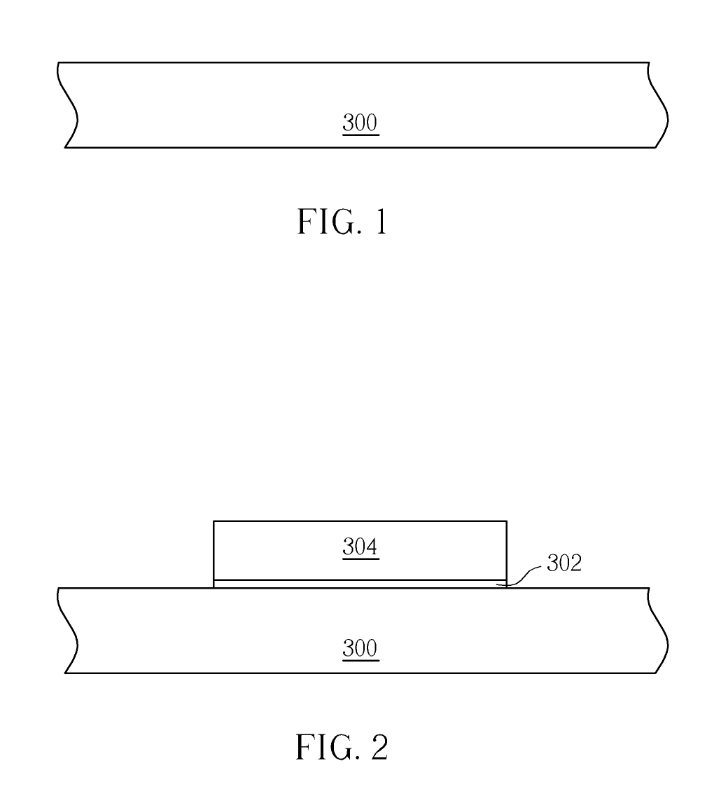

Please refer to FIG. 1 to FIG. 8, which illustrate schematic diagrams of the method of fabricating a memory cell in accordance with one embodiment of the present invention. As shown in FIG. 1, a substrate 300 is provided, such as a silicon substrate, an epitaxial silicon substrate, a silicon germanium substrate, a silicon carbide substrate or a silicon-on-insulator (SOI) substrate.

As shown in FIG. 2, a patterned dielectric layer 302 and a patterned first conductive layer 304 are formed on the substrate 300. For example, a dielectric layer (not shown) and a first conductive layer (not shown) are formed sequentially on the substrate 300. A photo-etching process (PEP) is carried out for forming the patterned dielectric layer 302 and the patterned first conductive layer 304. In one embodiment, the dielectric layer 302 includes a dielectric material such as SiO₂, and in one preferred embodiment, it includes a high-k dielectric material such as hafnium oxide (HfO₂), hafnium silicon oxide (HfSiO₄), hafnium silicon oxynitride (HfSiON), aluminum oxide (Al₂O₃), lanthanum oxide (La₂O₃), lanthanum aluminum oxide (LaAlO), tantalum oxide (Ta₂O₅), zirconium oxide (ZrO₂), zirconium silicon oxide (ZrSiO₄), hafnium zirconium oxide (HfZrO), yttrium oxide (Yb₂O₃), yttrium silicon oxide (YbSiO), zirconium aluminate (ZrAlO), hafnium aluminate (HfAlO), aluminum nitride (AlN), titanium oxide (TiO₂), zirconium oxynitride (ZrON), hafnium oxynitride (HfON), zirconium silicon oxynitride (ZrSiON), hafnium silicon oxynitride (HfSiON), strontium bismuth tantalite (SrBi₂Ta₂O₉, SBT), lead zirconate titanate (PbZrₓTi₁₋ₓO₃, PZT) or barium strontium titanate (BaₓSr₁₋ₓTiO₃, BST), but is not limited thereto. The patterned first conductive layer can be any conductive material, and in one embodiment, it is poly-silicon.

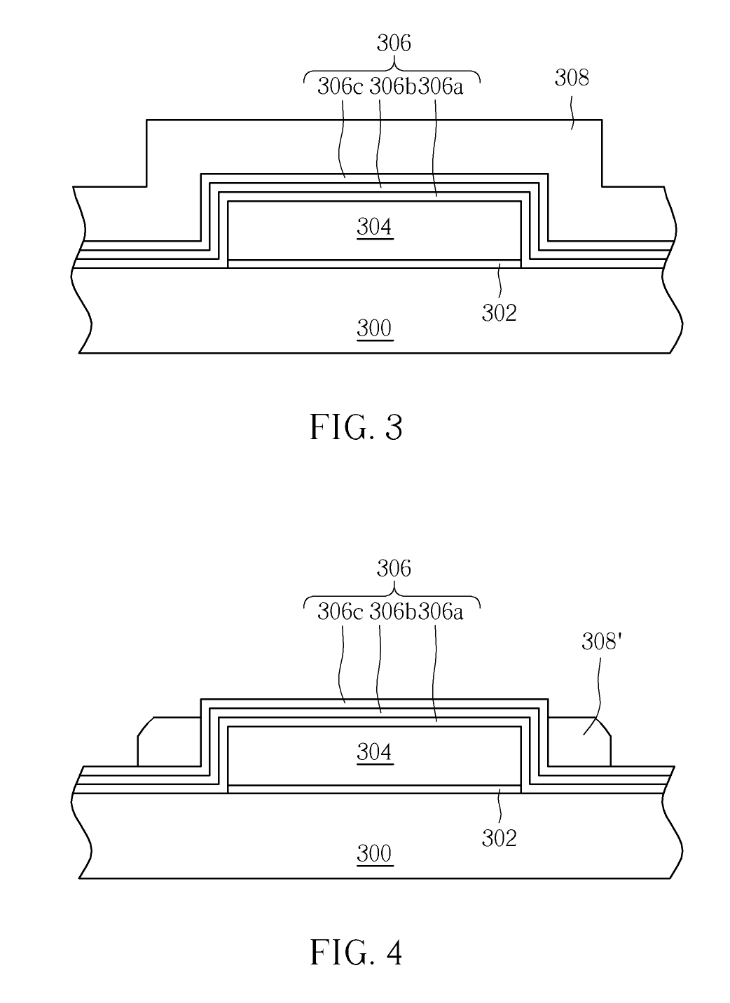

As shown in FIG. 3, a charge trapping layer 306 and a second conductive layer 308 are formed conformally on the patterned dielectric layer 302 and the patterned first conductive layer 304, for example, by a chemical vapor deposition (CVD) process. In one embodiment, the charge trapping layer 306 includes silicon nitride. In one embodiment, the charge trapping layer 306 has a first oxide layer 306a, a nitride layer 306b, and a second oxide layer 306c, thereby forming an ONO structure. Each layer of the ONO structure of the charge trapping layer 306 can be formed by different fabrication method. In one embodiment, all the first oxide layer 306a, the nitride layer 306b, and the second oxide layer 306c are formed by CVD processes. In another embodiment, the first oxide layer 306a can be formed by a thermal oxidation process, and the nitride layer 306b and the second oxide layer 306c are formed by CVD processes. The second conductive layer 308 can be any conductive material, such as poly-silicon. In one preferred embodiment, the second conductive layer 308 and the charge trapping layer 306 has an etching selectivity.

As shown in FIG. 4, an etching process is carried out to anisotropically remove a part of the second conductive layer 308, so the second conductive layer 308′ has a spacer structure with a curved sidewall at two sides of the patterned first conductive layer 304.

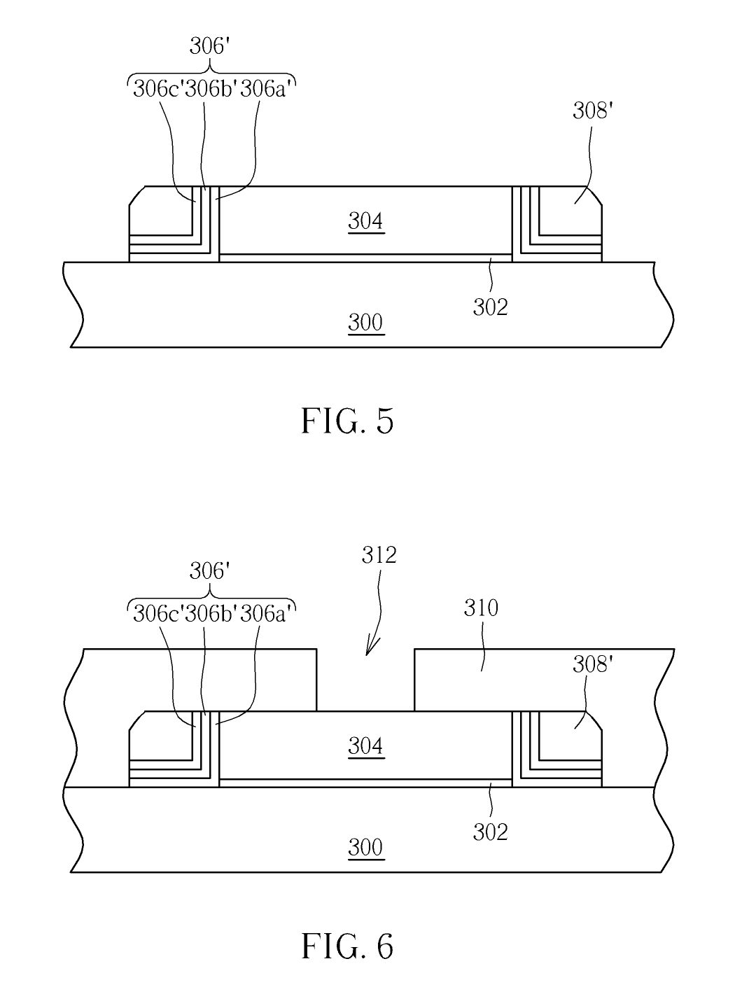

As shown in FIG. 5, another etching process is carried out to anisotropically remove a part of the charge trapping layer 306. Preferably, the charge trapping layer 306 over the patterned first conductive layer 304 is completely removed away. In one embodiment, when the charge trapping layer 306 includes ONO structure, there might be several etching processes to respectively remove the second oxide layer 306c, the nitride layer 306b and the first oxide layer 306a. In one embodiment, after removing the nitride layer 306b over the patterned first conductive layer 304, a washing process by using dilute hydrogen fluoride (DHF) is carried out to gently remove the first oxide layer 306a in avoiding damaging the patterned first conductive layer 304 and the substrate 300. After the etching process, the charge trapping layer 306′ has an L-shaped structure disposed between the patterned first conductive layer 304 and the second conductive layer 308′.

As shown in FIG. 6, a patterned mask layer 310 such as a photoresist layer is formed on the patterned first conductive layer 304, the second conductive layer 308′ and the charge trapping layer 306′. The patterned mask layer 310 directly contacts the patterned first conductive layer 304. The patterned mask layer 310 has an opening 312 disposed correspondingly above the patterned first conductive layer 304 and preferably aligns a central of the patterned first conductive layer 304.

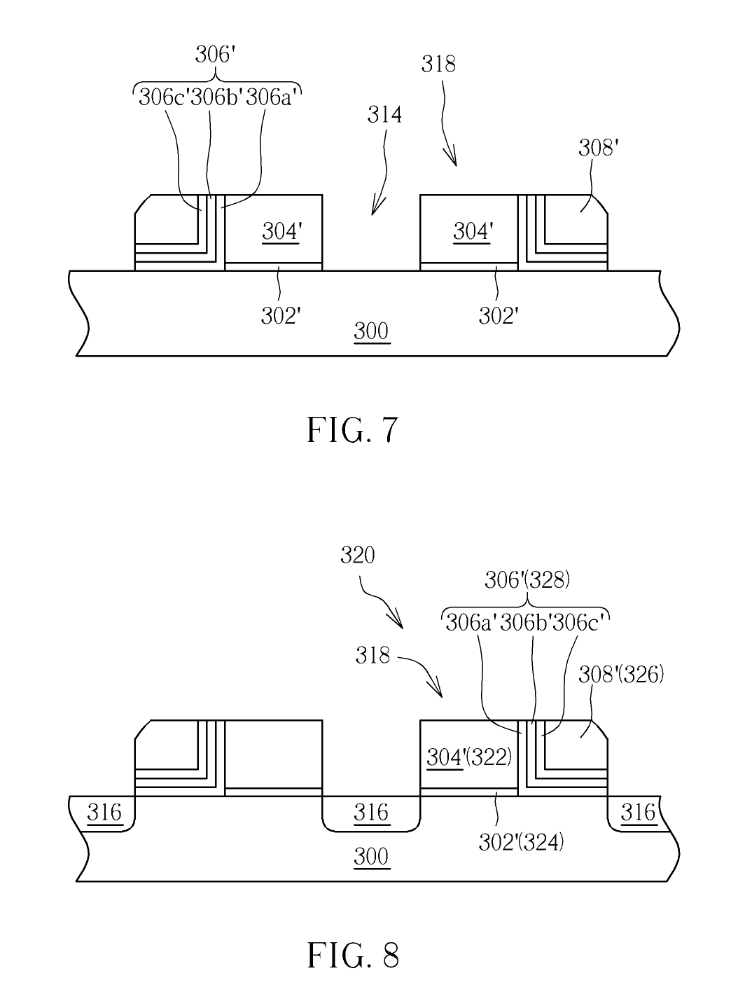

As shown in FIG. 7, an etching process is carried out by using the patterned mask layer 310 as a mask to remove the patterned first conductive layer 304 and the patterned dielectric layer 302. A trench 314 exposing the substrate 300 is therefore formed. By doing this, two separated gate stack structures 318 are formed on the substrate 300 and each of which is mirror symmetrical with each other along the trench 314. Each gate stack structure 318 includes the patterned dielectric layer 302′, the patterned first conductive layer 304′, the charge trapping layer 306′ and the second conductive layer 308′. It is noted that the patterned first conductive layer 304′ has a vertical sidewall facing the trench 314.

As shown in FIG. 8, a source/drain region 316 is formed in the substrate 300 at two sides of the gate stack structure 318. A memory cell 320 is therefore formed. As shown in FIG. 8, the memory cell 320 includes the substrate 300, a gate dielectric layer 324 (formed from the patterned dielectric layer 302′), a selection gate 322 (formed from the patterned first conductive layer 304′) disposed on the gate dielectric layer 324, a main gate 326 (formed from the second conductive layer 308′) disposed on the gate dielectric layer 324, a charge trapping structure 328 (formed from the charge trapping layer 306′) disposed between the selection gate 322 and the main gate 326 and further between the main gate 326 and the gate dielectric layer 324 and the source/drain region 316 disposed in the substrate 300 at two sides of the main gate 326 and the selection gate 322.

With reference to FIG. 6 and FIG. 7, since the width of the selection gate 322 (the patterned first conductive layer 304′ in FIG. 7) is defined by the width of the opening 312 in FIG. 6, a selection gate 322 with smaller width can be fabricated by using an opening 312 with bigger width, therefore releasing the photo window. Moreover, with reference to FIG. 6, since there is no other layers above the patterned first conductive layer 304, the etching process is comparatively simple. In addition, since the patterned first conductive layer 304 is a flat film, the photo-etching process for forming the trench 314 and defining the selection gate 322 can be carried out more precisely.

In light of above, the present invention provides a method of manufacturing a memory cell. The selection gate can be defined more precisely because the photo window is released and the etching process is relatively easy. Both time and cost can be streamlined and products with good performance can be provided by using the method provided in the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A method of manufacturing a memory cell, comprising:
providing a substrate;
forming a patterned dielectric layer and a patterned first conductive layer on the substrate;
forming a first charge trapping layer, a second charge trapping layer and a third charge trapping layer sequentially stacked on the patterned first conductive layer and the patterned dielectric layer;
performing an etching process to remove the third charge trapping layer and the second charge trapping layer over the patterned first conductive layer;
performing a washing process to remove the first charge trapping layer over the patterned first conductive layer and to form a charge trapping structure;
forming a main gate on a sidewall of the patterned dielectric layer and the patterned first conductive layer;
removing a portion of the patterned first conductive layer and a portion of the patterned dielectric layer until exposing the substrate; and
forming at least a source/drain region in the substrate.

2. The method of manufacturing a memory cell according to claim 1, wherein the step of forming the charge trapping structure and the main gate comprises:
forming the first charge trapping layer, the second charge trapping layer, the third charge trapping layer and a second conductive layer conformally on the patterned first conductive layer and the patterned dielectric layer;
anisotropically removing the second conductive layer to form the main gate; and
performing the etching process and the washing process to form the charge trapping structure.

3. The method of manufacturing a memory cell according to claim 1, wherein after the washing process, the third charge trapping layer, the second charge trapping layer and the first charge trapping layer over the patterned first conductive layer are completely removed.

4. The method of manufacturing a memory cell according to claim 1, wherein the main gate comprises a spacer structure.

5. The method of manufacturing a memory cell according to claim 1, wherein the charge trapping structure comprises an L-shaped structure.

6. The method of manufacturing a memory cell according to claim 1, wherein the charge trapping structure comprises an ONO structure.

7. The method of manufacturing a memory cell according to claim 1, wherein the step of removing a portion of the patterned first conductive layer and a portion of the patterned dielectric layer comprises:
forming a patterned mask layer having an opening on the patterned first conductive layer and a portion of the patterned dielectric layer; and
etching the patterned first conductive layer and the patterned dielectric layer by using the patterned mask layer as a mask.

8. The method of manufacturing a memory cell according to claim 7, wherein the patterned mask layer directly contacts the patterned first conductive layer.

9. The method of manufacturing a memory cell according to claim 1, wherein the patterned first conductive layer forms a select gate of the memory cell.

10. The method of manufacturing a memory cell according to claim 9, wherein the selection gate has a vertical sidewall.
